(19) United States
(12) Patent Application Publication
(10) Pub. No.: US 2024/0339990 A1
(43) Pub. Date: Oct. 10, 2024

(54) SMART ELECTRONICALLY RESETTABLE FUSE WITH LOAD PRE-CHARGING

(71) Applicant: GM Global Technology Operations LLC, Detroit, MI (US)

(72) Inventors: Chandra S. Namuduri, Troy, MI (US); Rashmi Prasad, Troy, MI (US); Muhammad Hussain Alvi, Troy, MI (US)

(21) Appl. No.: 18/296,478

(22) Filed: Apr. 6, 2023

(51) Int. Cl. H03K 3/017; H02J 7/00; H02M 1/00

(52) U.S. Cl. CPC H03K 3/017; H02J 7/0029; H02J 7/0047; H02J 7/0063; H02M 1/0009; H02J 2207/20

(57) ABSTRACT

Power converters on a vehicle may provide electrical power to propulsion and non-propulsion vehicle systems from a battery source. Power converters may include DC link capacitors. An electronically resettable fuse may pass electric current between the battery source and the power converters through a switch module. The switch module may be controlled in a pre-charge mode and a circuit protection mode, wherein the pre-charge mode limits a rate of charging of the DC link capacitor by controlling the electric current with the switch module.

### INTRODUCTION

The present disclosure relates to vehicles and more particularly to a smart electronically resettable fuse.

An electrified vehicle may include an electrical system having separate high-voltage and low-voltage buses. While “high-voltage” and “low-voltage” are relative terms, “low-voltage” may encompass a maximum voltage level of twelve to fifteen volts (i.e., an auxiliary voltage) with the term “high-voltage” describing voltage levels well above auxiliary voltage levels. A high-voltage bus may be used to source power to a propulsion system in an electrified vehicle, for example through power electronics including a multi-phase inverter. A high-voltage bus may be used to source power to other high-voltage vehicle systems (e.g., electrically driven air conditioning compressors) through an auxiliary power module (APM) (e.g., power converter). A high-voltage bus may also source power to a low-voltage bus through an APM (e.g., power converters). High-voltage bus voltage may range between sixty and eight hundred volts, for example. A high-voltage bus may couple to a high-voltage (HV) direct current (DC) battery pack which may provide the main or only electrical energy storage for the vehicle. A low-voltage bus may couple to a low-voltage battery or may be powered exclusively from a high-voltage DC battery pack through an associated APM.

Strategically positioned high-current fuses and high-voltage switches help ensure voltage isolation in the event of a fault condition within high-voltage busses, with the switches also opened during routine shut down procedures. However, certain vehicle electrical loads may require a power source continually or periodically during periods of vehicle shutdown.

### SUMMARY

In one exemplary embodiment, a method may include controlling a gate driver to cause a switch module of an electronically resettable fuse to control an electric current to pre-charge a DC link capacitor of a power converter, monitoring, using a microcontroller, an electric circuit of a vehicle, the electric circuit including a battery source and a load including the power converter, wherein the battery source supplies electric power to the load, detecting, using the microcontroller, a high current event in the electric circuit by comparing a current level of a current flowing through the electric circuit to a time-based current threshold, and responsive to detecting the high current event, controlling the gate driver to cause the switch module of the electronically resettable fuse to open the electric circuit to stop the flow of the current through the electric circuit.

In addition to one or more of the features described herein, the method may further include updating the time-based current threshold based at least in part on data collected from other vehicles.

In addition to one or more of the features described herein, the switch module may include a switch device and controlling the electric current may include pulse width modulation of the switch device.

In addition to one or more of the features described herein, the switch module may include a switch device and controlling the electric current may include controlling the switch device in a linear operating region.

In addition to one or more of the features described herein, the switch module may include a first switch device and a second switch device wherein the first switch device is in series with a current limiting resistor and controlling the electric current may include controlling the first switch device on.

In another exemplary embodiment, a vehicle may include an on-vehicle battery source to provide electric current to an electric circuit including a power converter with a direct current (DC) link capacitor, an electronically resettable fuse for passing the electric current between the battery source and the electric circuit, and a microcontroller to selectively control the electronically resettable fuse in one of a pre-charge mode and a circuit protection mode, wherein the pre-charge mode limits a rate of charging of the DC link capacitor with the electric current.

In addition to one or more of the features described herein, the power converter may include one of a power inverter providing a multi-phase alternating current (AC) output to an electric machine and a DC/DC power converter providing a DC output to an auxiliary load.

In addition to one or more of the features described herein, the DC output to the auxiliary load may include a DC output at a voltage level that is less than or equal to the voltage level of the battery source.

In addition to one or more of the features described herein the DC output to the auxiliary load may include a DC output at a voltage level that is greater than or equal to the voltage level of the battery source.

In addition to one or more of the features described herein, the power converter may include a power inverter and an associated electric machine windings selectively reconfigured and controlled to function as a buck or boost mode converter.

In addition to one or more of the features described herein, the power converter may be coupled to off-vehicle loads through a charge port.

In addition to one or more of the features described herein, the power converter may include the DC/DC power converter and the pre-charge mode and the circuit protection mode remain active during a key-off non-propulsion mode of the vehicle.

In yet another exemplary embodiment, an electric circuit may include a battery source to provide electric current to a power converter with a direct current (DC) link capacitor, an electronically resettable fuse for passing the electric current between the battery source and the power converter through a switch module, and a microcontroller to selectively control the electronically resettable fuse in one of a pre-charge mode and a circuit protection mode, wherein the pre-charge mode limits a rate of charging of the DC link capacitor by controlling the electric current with the switch module.

In addition to one or more of the features described herein, the switch module may include a switch device and controlling the electric current with the switch module includes pulse width modulation of the switch device.

In addition to one or more of the features described herein, the pulse width modulation of the switch device may include a fixed duty cycle.

In addition to one or more of the features described herein, the pulse width modulation of the switch device may include a variable duty cycle.

In addition to one or more of the features described herein, the switch module may include a switch device and controlling the electric current with the switch module may include controlling the switch device in a linear operating region.

In addition to one or more of the features described herein, the switch module may include a first switch device and a second switch device wherein the first switch device is in series with a current limiting resistor and controlling the electric current with the switch module may include controlling the first switch device on.

In addition to one or more of the features described herein, the electric circuit may include a transient voltage suppression device across the switch module.

In addition to one or more of the features described herein, the switch module may include a bi-directional switch device.

The above features and advantages, and other features and advantages, of the disclosure are readily apparent from the following detailed description when taken in connection with the accompanying drawings.

### BRIEF DESCRIPTION OF THE DRAWINGS

Other features, advantages, and details appear, by way of example only, in the following detailed description, the detailed description referring to the drawings in which:

FIG. 1 depicts a schematic of an example of a plug-in hybrid-electric vehicle (PHEV), according to one or more embodiments described herein;

FIG. 2 depicts an electrical system that includes a traction battery, a power inverter module, and an electric machine, according to one or more embodiments described herein;

FIGS. 3A and 3B depict exemplary configurations for an electric circuit, according to one or more embodiments described herein;

FIGS. 4A and 4B depict pre-charging using switch device pulse width modulation control and a corresponding hardware block diagram, according to one or more embodiments described herein;

FIGS. 5A and 5B depict pre-charging using switch device linear control and a corresponding hardware block diagram, according to one or more embodiments described herein;

FIGS. 6A and 6B depict pre-charging using current limiting resistance and a corresponding hardware block diagram, according to one or more embodiments described herein;

FIG. 7 depicts a schematic diagram of the microcontroller of FIGS. 3A and 3B according to one or more embodiments described herein; and

FIG. 8 depicts a flow diagram of a method for monitoring an electric circuit according to one or more embodiments described herein.

### DETAILED DESCRIPTION

The following description is merely exemplary in nature and is not intended to limit the present disclosure, its application, or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

Fuses are circuit elements that may transition from a closed state to an open state (e.g., an open circuit) to prevent current flow when current exceeds a certain threshold. Resettable fuses may transition between closed states and open states based on the current flow within an electrical system. For example, resettable fuses may transition to the open state to mitigate overcurrent faults within the electrical system.

The technical solutions described herein provide for a selectively controllable (smart) electronically resettable fuse to detect high current events (overcurrent) to prevent the high current from causing damage, such as to a power source or load. Additionally, load pre-charge functions may be provided to prevent excessive load inrush current and power to an electrical circuit and load which may not be at a voltage level equivalent or close to a source voltage coupled thereto. According to one or more embodiments described herein, a control architecture is provided that implements an isolation boundary, a microcontroller, and sensors to provide information to an electronically resettable fuse to provide multiple functionalities and application-based optimization. As used herein, an electronically resettable fuse may include, among other things, a semiconductor based fuse. Such a control architecture provides fast response times, is resettable, is low maintenance, and is independent of operating conditions. Various control and hardware implementations corresponding to the load pre-charge functions are disclosed in accordance with one or more embodiments.

Conventional approaches to overcurrent detection may be insufficient. For example, traditional fuses use resistive heating to melt a current carrying element to protect the downstream system from overcurrent damage. Such conventional approaches are slow, with typical response times of 5-100 s of milliseconds, do not support multiple or adjustable thresholds for overcurrent, and are susceptible to false trigger events. These conventional approaches also require maintenance (e.g., replacement after the occurrence of an overcurrent event). Conventional approaches to load pre-charging may require multiple electrically controlled mechanical contactors, current limiting resistors and particular switch sequencing to prevent excessive load inrush current and power and to prevent contactor arcing and welding during contactor closing (e.g., connecting) and opening (e.g., disconnecting).

One or more embodiments described herein address these and other conditions by using a microcontroller to monitor an electric circuit, pre-charge the electric circuit, detect a high current event in the electric circuit based on a time-based current threshold, and control a gate driver to cause an electronically resettable fuse to open the electric circuit to stop the flow of the current. In an embodiment, a control and sensing architecture is provided for microsecond scale shutdown (response time) while avoiding false triggers. In an embodiment, fault detection (e.g., a high current (or “overcurrent”) event) is based upon one or more thresholds that are time-based and may be adjusted. As used herein, a time-based current threshold is a threshold that has a time limit and a current level limit. A fault (e.g., a high current event) is said to occur when the current level limit is exceeded for a duration that meets or exceeds the time limit. In an embodiment, system diagnostics may be performed using data driven fault detection. In an embodiment, a defined isolation boundary may be used to define portions of the circuit as high-voltage and low-voltage, and suitable components may be used within the high and low-voltage portions.

One or more embodiments herein provide improvements over conventional fuses because electronically resettable fuses are faster, resettable, and precise; avoid false triggers by using a control system (e.g., a microcontroller) to detect and shutdown faults with fast response time; and may be made smarter to provide multi-functionality by utilizing sensing of current, voltage, and temperature. One or more embodiments herein may eliminate electrically controlled mechanical contactors. These and other advantages are described in more detail herein.

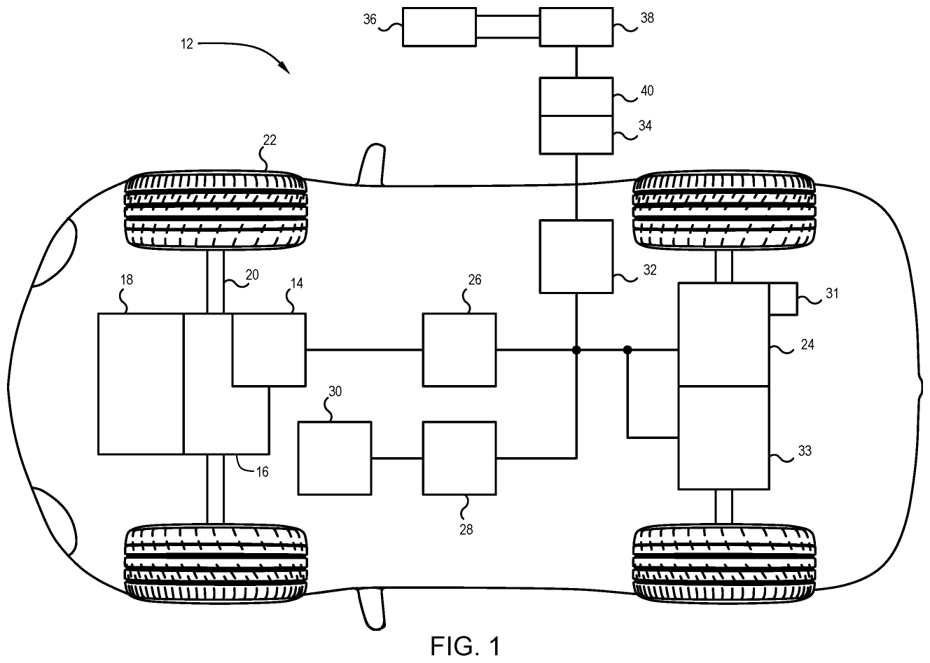

FIG. 1 depicts a schematic of an exemplary plug-in hybrid-electric vehicle (PHEV). A vehicle 12 may include one or more electric machines 14 mechanically connected to a hybrid transmission 16. The electric machines 14 may be capable of operating as a motor and/or a generator. In addition, the hybrid transmission 16 may be mechanically connected to an engine 18. The hybrid transmission 16 may also be mechanically connected to a drive shaft 20 that is mechanically connected to the wheels 22. The electric machines 14 may provide propulsion and deceleration capability when the engine 18 is turned on or off or is not present. The electric machines 14 may also function as generators and may provide fuel economy benefits by recovering energy that would normally be lost as heat in the friction braking system.

An on-vehicle battery pack 24 stores and provides energy that may be used by the electric machines 14 or other vehicle 12 components. The battery pack 24 may provide a high-voltage DC output from one or more battery cell arrays, sometimes referred to as battery cell stacks, within the battery pack 24. The high-voltage DC output from the battery pack 24 may be referred to as source voltage Vs. The high-voltage DC output from the battery pack 24 may also be converted to different DC voltage levels (e.g., higher or lower) for on and off vehicle uses and applications. For example, in a “key on” propulsion mode, the battery pack 24 may be electrically connected to one or more power inverter modules 26 used for vehicle propulsion. The power inverter modules 26 may be electrically connected to the electric machines 14 and provides the ability to bi-directionally transfer electrical energy between the battery pack 24 and the electric machines 14. During a “key off” non-propulsion mode, the battery pack 24 may be disconnected from the one or more power inverter modules 26. For example, a typical battery pack 24 may provide a DC voltage while the electric machines 14 may use a three-phase alternating current (AC) voltage to function. The power inverter module 26 may convert the DC voltage to a three-phase AC voltage as used by the electric machines 14 for vehicle propulsion. In a regenerative mode, the power inverter module 26 may convert the three-phase AC voltage from the electric machines 14 acting as generators to the DC voltage used by the battery pack 24. The description herein may be applicable to a pure electric vehicle or other hybrid vehicles. For a pure electric vehicle, the hybrid transmission 16 may be a gear box connected to an electric machine 14 and the engine 18 may not be present.

In addition to providing energy for propulsion, the battery pack 24 may provide energy for other vehicle electrical systems and loads, or other off-vehicle loads including other vehicles. Off-vehicle loads, including other vehicles and their loads (e.g., batteries), may be coupled to the battery pack 24 through a charge port coupled to a power converter. The vehicle 12 electrical system may include one or more DC/DC power converter modules 28 that convert the high-voltage DC output of the battery pack 24 to a lower, higher or equivalent DC voltage that is compatible with other non-propulsion electrical loads 30 including auxiliary batteries. Non-propulsion electrical loads may be referred to as auxiliary loads. It may be desirable that non-propulsion electrical loads be provided with electrical power during “key off” non-propulsion modes. Thus, during “key off” non-propulsion modes, the battery pack 24 may be electrically connected to one or more power converter modules 28 used for providing electrical power to non-propulsion electrical loads. Power inverters and power converters may include DC link capacitors coupled across positive and negative DC bus conductors. Unless specifically identified, converter is understood to refer to any of a DC/DC converter, DC/AC inverter or AC/DC converter, including a power inverter and associated electric machine windings selectively reconfigured and controlled to function as a buck or boost mode converter.

A battery electrical control module (BECM) 33 may be in communication with the battery pack 24. The BECM 33 may function as a controller for the battery pack 24 and may also include an electronic monitoring system that manages temperature and charge state of each of the battery cells. The battery pack 24 may have a temperature sensor 31, such as a thermistor or other temperature gauge. The temperature sensor 31 may be in communication with the BECM 33 to provide temperature data regarding the battery pack 24. The temperature sensor 31 may also be located on or near the battery cells within the battery pack 24. It is also contemplated that more than one temperature sensor 31 may be used to monitor temperature of the battery cells.

The vehicle 12 may be, for example, an electric vehicle such as a plug-in hybrid-electric vehicle (PHEV), a full hybrid-electric vehicle (FHEV), a mild hybrid-electric vehicle (MHEV), or a battery electric vehicle (BEV) in which the battery pack 24 may be recharged by an external power source 36. The external power source 36 may be a connection to an electrical outlet. The external power source 36 may be electrically connected to electric vehicle supply equipment (EVSE) 38. The EVSE 38 may provide circuitry and controls to regulate and manage the transfer of electrical energy between the power source 36 and the vehicle 12. The external power source 36 may provide DC or AC electric power to the EVSE 38. The EVSE 38 may have a charge connector 40 for plugging into a charge port 34 of the vehicle 12. The charge port 34 may be any type of port configured to transfer power from the EVSE 38 to the vehicle 12. The charge port 34 may be electrically connected to a charger or on-board power conversion module 32. The power conversion module 32 may condition the power supplied from the EVSE 38 to provide the proper voltage and current levels to the battery pack 24. The power conversion module 32 may interface with the EVSE 38 to coordinate the delivery of power to the vehicle 12. The EVSE connector 40 may have pins that mate with corresponding recesses of the charge port 34.

The various components discussed may have one or more associated controllers to control and monitor the operation of the components. The controllers may communicate via a serial bus (e.g., Controller Area Network (CAN)) or via discrete conductors.

The battery cells may include electrochemical cells that convert stored chemical energy to electrical energy. The cells may include a housing or pouch, a positive electrode (cathode) and a negative electrode (anode). An electrolyte may allow ions to move between the anode and cathode during discharge, and then return during recharge. Terminals may allow current to flow out of the cell for use by the vehicle. When positioned in an array with multiple battery cells, the terminals of each battery cell may be aligned with opposing terminals (positive and negative) adjacent to one another and a busbar may assist in facilitating a series connection between the multiple battery cells. The battery cells may also be arranged in parallel such that similar terminals (positive and positive or negative and negative) are adjacent to one another. For example, two battery cells may be arranged with positive terminals adjacent to one another, and the next two cells may be arranged with negative terminals adjacent to one another. In this example, the busbar may contact terminals of all four cells. The battery pack 24 may be heated and/or cooled using a liquid thermal management system, an air thermal management system, or other method as known in the art.

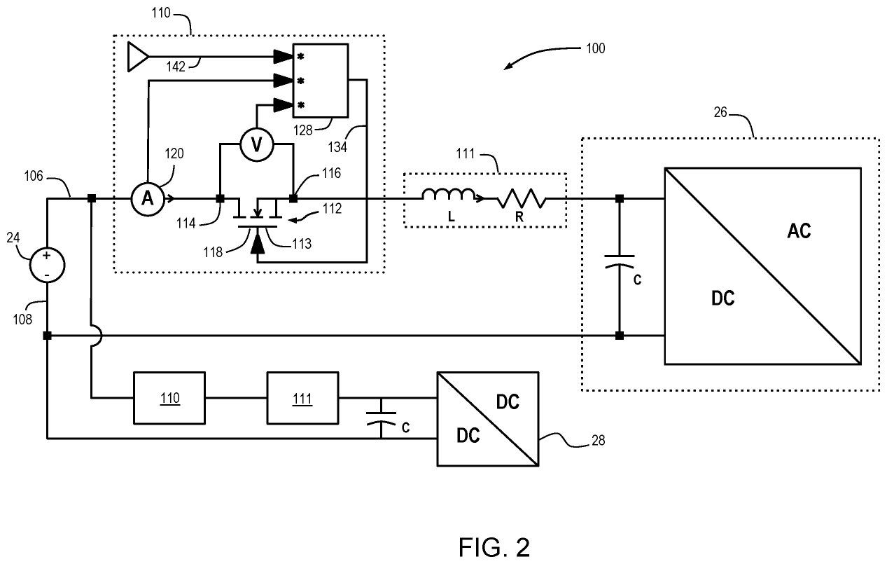

FIG. 2 depicts an exemplary electrical system 100 that includes the battery pack 24, a power inverter module 26, and a power converter module 28. In each of the exemplary power inverter module 26 and power converter module 28, a DC link capacitor C may be connected across positive and negative connectors 106, 108, respectively, as illustrated in FIG. 2. The electrical system 100 further includes a respective electronically resettable fuse device 110 corresponding to each power inverter module 26 and power converter module 28. As shown, each electronically resettable fuse device 110 may be connected between the battery pack 24 and the power inverter module 26. Reference characters L and R represent inductance and resistive circuit elements, respectively, of intrinsic LR networks 111 that may be present in the electrical coupling between the electronically resettable fuse devices 110 and the power inverter module 26 and power converter module 28. In example implementation, the electrical connection may include any suitable electrical connections, such as an electrical connector, cable, bus bar, etc.

The electronically resettable fuse device 110 may be used to provide control and protection to the coupled electrical loads (e.g., power inverter modules 26, power converter modules 28, and associated electrical loads) as well as a power source (e.g., the battery pack 24). The electronically resettable fuse device 110 may cause current to cease flowing to the electric circuit based on present and/or historical current levels. This provides for fast fault detection without false triggers. Further, this data driven approach provides for diagnosing fault conditions. For example, predictions may be made based on waveforms of the electronically resettable fuse device 110, which may then be used to set thresholds for the present vehicle 12 and/or for other vehicles. Additionally, the electronically resettable fuse device 110 may be used in pre-charging of the power inverter modules 26 and power converter modules 28 (e.g., the DC link capacitors C).

As illustrated in detail with respect to the exemplary embodiment associated with the power inverter module 26 but also applicable to power converter modules 28, the electronically resettable fuse devices 110 may include a switch module 112, such as a single voltage-controlled switch device 113. Examples of voltage-controlled switch devices may be an IGBT, MOSFET, superjunction MOSFET, FET, JFET, semiconductor power switch device made of Silicon, SiC, GaN or other WBG or UWBG materials, or other suitable switch having a corresponding gate to which a gate signal is applied to change the on/off state of a given switch. The switch device 113 may include a first terminal 114, a second terminal 116, and a gate terminal 118. The first terminal 114 and the second terminal 116 may be arranged such that the switch device 113 is in series along the positive connector 106 to control current flow between the battery pack 24 and the power inverter module 26.

The electronically resettable fuse device 110 may also include a sensor 120. According to one or more embodiments described herein, the sensor 120 may be a current sensor, a temperature sensor, a voltage sensor, or any other suitable sensor (including combinations thereof) to sense a condition of the electrical system 100. In an example in which the sensor 120 is a current sensor, the sensor 120 may be connected along the positive connector 106 and measure an amount of current passing through the positive connector 106 (e.g., a current level of a current flowing through the electric circuit). In this example, the sensor 120 may be or include any suitable sensor that may directly measure current and generate a signal indicative of a measured overcurrent. The sensor 120 may be configured to generate the overcurrent signal based on an instantaneous current threshold, such as a predetermined value above a maximum operating current. For example, the sensor 120 may measure the current level to detect an instantaneous high current event in the electric circuit by comparing the current level of the current flowing through the electric circuit to the instantaneous current threshold. In an example where the sensor 120 is a temperature sensor, the electronically resettable fuse device 110 may trigger a shutdown (i.e., open the electric circuit to prevent the flow of electricity through the electric circuit) based upon a high temperature condition, which may be determined using a temperature threshold. In another example where the sensor 120 is a voltage sensor, the electronically resettable fuse device 110 may trigger a shutdown (i.e., open the electric circuit to prevent the flow of electricity through the electric circuit) based upon a high-voltage condition, which may be determined using a voltage threshold.

While the illustrated embodiment of FIG. 2 shows the switch module 112 as a single voltage-controlled switch device 113 (e.g., IGBT) suitable for uni-directional control, certain applications may benefit from bi-directional control of a symmetrical device (i.e., bi-directional voltage and current blocking). Thus, in an embodiment, the switch module 112 may include multiple switch devices 113 arranged, for example, in anti-parallel or back-to-back configurations, or alternative known bi-directional switch devices.

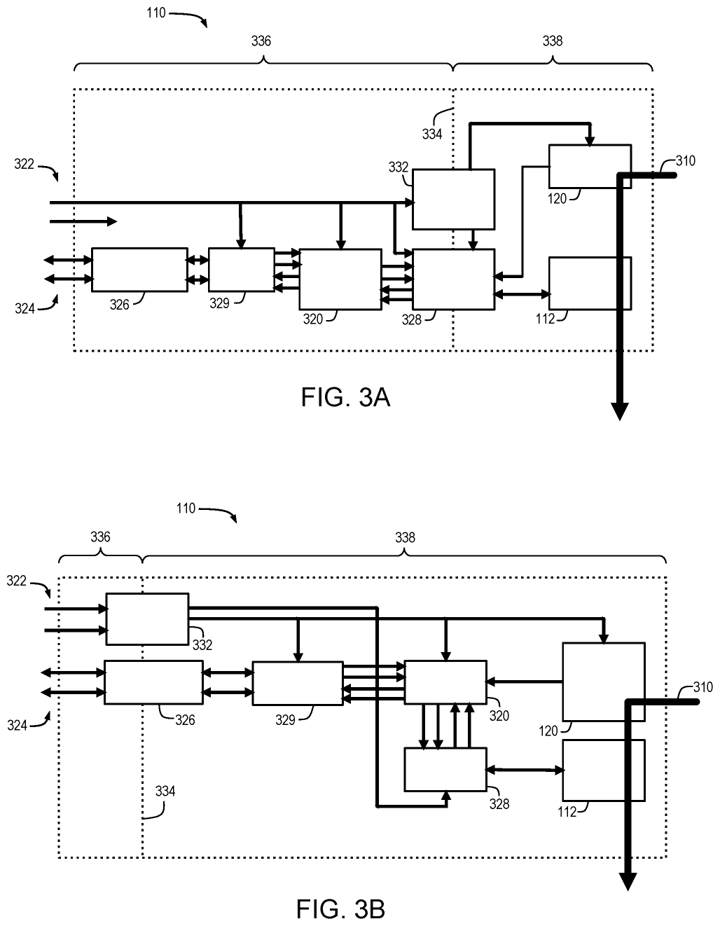

In some examples, such as the examples shown in FIGS. 3A and 3B, a microcontroller may be used to control a gate driver 328. Particularly, FIGS. 3A and 3B depict schematic diagrams of the electronically resettable fuse device 110 controlled by a microcontroller 320. As shown, a high-power current 310 flows through or in proximity to the sensor 120 and the switch module 112 (see also, FIG. 2) of the electric circuit.

An isolation boundary 334 separates a low-voltage portion 336 of the electric circuit from a high-voltage portion 338 of the electric circuit. The electric circuit may include high-voltage components that are positioned within the low-voltage portion 336 and high-voltage components that are positioned within the high-voltage portion 338 or vice versa meaning low-voltage components on the high-voltage side. Bias power 322 and control signals 324 are received at the low-voltage portion 336.

As may be seen by comparing FIGS. 3A and 3B, the isolation boundary 334 may be located at different points within the electric circuit to isolate the low-voltage portion 336 from the high-voltage portion 338. In each case, the sensor 120 and the switch module 112 are located within the high-voltage portion 338. However, other components may be low or high-voltage components depending on the location of the isolation boundary 334. For example, in FIG. 3A, an isolated transformer 326, an iso-SPI driver 329, and the microcontroller 320 are arranged within the low-voltage portion 336 as shown. An isolated power supply 332 and the gate driver 328 sit on the isolation boundary 334 and thus interact with both components in the high-voltage portion 338 and components in the low-voltage portion 336.

In the example of FIG. 3B, the isolation boundary 334 is shifted such that more of the components are arranged within the high-voltage portion 338. Specifically, the microcontroller 320, the gate driver 328, and the iso-SPI driver 329 are arranged in the high-voltage portion 338 of the electric circuit as shown along with the sensor 120 and the switch module 112. The isolated transformer 326 and the isolated power supply 332 sit on the isolation boundary 334 and thus interact with both components in the high-voltage portion 338 and components in the low-voltage portion 336.

In the example of FIG. 3A, the microcontroller 320 is positioned within the low-voltage portion 336. However, this arrangement uses a relatively more complex and/or expensive gate driver 328 in contrast to the example of FIG. 3B. More particularly, the example of FIG. 3B positions the microcontroller 320 within the high-voltage portion 338 so that a relatively less complex and/or expensive gate driver 328 may be implemented.

In an embodiment, the electronically resettable fuse devices 110 may include additional elements associated with pre-charging and disconnect functionality including a low-power solid-state switch device and current limiting resistor, a low-range (e.g., milliamps) current sensor and high-range (e.g., tens of amps) current sensor or a dual range current sensor, a transient voltage suppression device (e.g., snubber circuit or MOV (Metal Oxide Varistor)), and linear mode gate control circuitry.

Operation of the electronically resettable fuse device 110 in a circuit protection mode may be controlled by detecting a high current event in an electric circuit (e.g., the electrical system 100) by comparing a current level of current flowing through the electric circuit to a time-based current threshold and then controlling a controller gate driver element 128 connected to the switch device 113 as shown in FIG. 2. According to one or more embodiments described herein, the resettable fuse device 110 may include a gate driver and a controller (e.g., a microcontroller) to provide a control signal to the gate driver to apply the signal to the switch device 113. As an example, with reference to FIG. 3A, the resettable fuse device 110 may include an isolation transformer 326, an isolated serial peripheral interface (iso-SPI) driver 329, a microcontroller 320, a gate driver 328, and an isolated power supply 332, although other configurations of resettable fuse device 110 elements are possible. For example, the iso-SPI driver may be replaced with an isolated controller area network (CAN) transceiver. As described herein, the time-based current threshold is a threshold that has a time limit and a current level limit. A fault (e.g., a high current event) is said to occur when the current level limit is exceeded for a duration that meets or exceeds the time limit. During operation, the electronically resettable fuse device 110 may allow current flow through the electrical system 100. However, in the event that a high current event is detected based on the time-based current threshold (e.g., the current level of the current flowing through the electric circuit meets or exceeds the current level limit for a duration exceeding the time limit), the electronically resettable fuse device 110 may prevent current flow until a reset signal 142 is received.

The controller gate driver element 128 may receive input as shown in FIG. 2. The input may be the voltage across the switch device 113 (via the first terminal 114 and the second terminal 116), the output of the current sensor 120, and the reset signal 142. The controller gate driver element 128 may measure a voltage drop across the switch device 113 via the first terminal 114 and the second terminal 116, which may correspond to a short circuit fault current. The controller gate driver element 128 may also receive a reset signal 142 that may cause the controller gate driver element 128 to output the control signal that transitions the switch device 113 from the open state to the closed state.

The controller gate driver element 128 may generate a control signal that controls operation of the switch device 113 based on the received inputs as shown in FIG. 2. For example, the controller gate driver element 128 may be a MOSFET driver that translates the received input signals to corresponding voltage signals that control operation of the switch device 113. The switch device 113 may transition between an open state (e.g., an off-state) and a closed state (e.g., an on-state). The closed state corresponds to a full on saturation state of the switch device 113. In the open state, the switch device 113 prevents current flowing through the electric circuit, and the switch device 113 allows current to flow through the electric circuit when in the closed state. The controller gate driver element 128 may provide the control signal to the gate terminal 118 of the switch device 113 via an output 134.

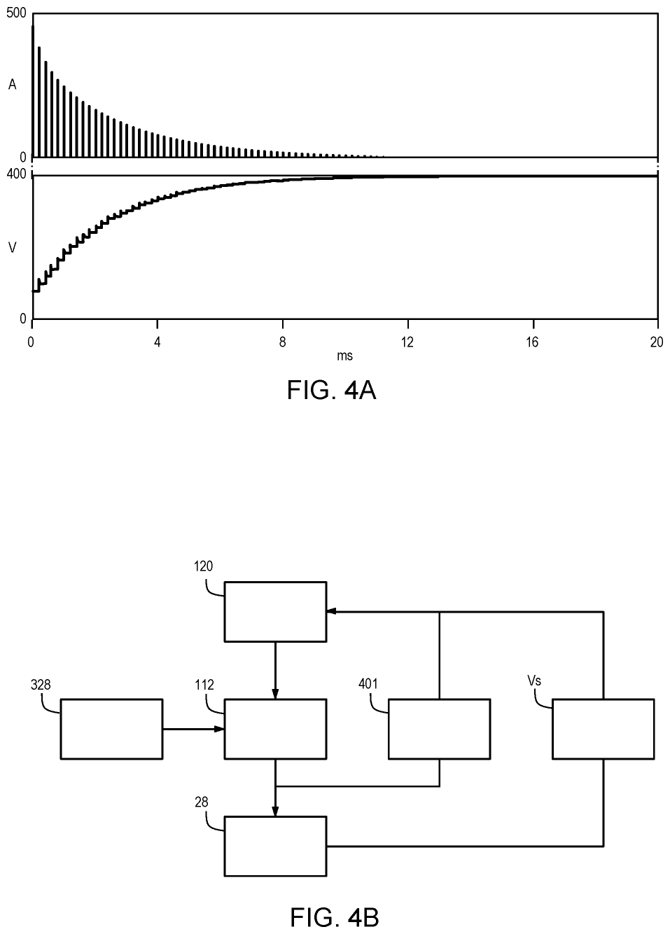

In an embodiment, the electronically resettable fuse device 110 may be operated in a pre-charge mode wherein the gate driver 328 operates the switch module 112 in a pulse width modulation (PWM) mode with a fixed or variable duty cycle for controllably pre-charging of the DC link capacitor C. The switch module 112 in the present embodiment may be a single switch device which may be controlled closed by the gate driver 328 and current will rise in accordance with the time constant of the intrinsic LR network 111 until current measured through the sensor 120 (e.g., a current level of a current flowing into the DC link capacitor C) reaches a predetermined level after which the switch module 112 may be controlled open. Repetitive cycling of the switch module 112 in this manner builds up charge on the DC link capacitor thus increasing its voltage. FIGS. 4A and 4B illustrate an exemplary fixed pulse width implementation of the PWM mode with time shown horizontally in milliseconds (ms). The top chart of FIG. 4A plots the current in amps (A) with respect to time into a 10 uF DC link capacitor C from nominally zero volts being pre-charged from a 400 volt DC source in response to a 5 kHz PWM signal with a 0.5% duty cycle (i.e., 1 microsecond on). The bottom chart of FIG. 4A plots the voltage (V) with respect to time across the 10 uF DC link capacitor C (Vcap) being pre-charged in accordance with the top chart. It is appreciated that the power dissipation through the switch module 112 is manageable owing to the low duty cycle; however, higher peak currents particularly at the beginning of the pre-charging may be associated with higher stresses on the switch module 112. But, advantageously, full charging of the DC link capacitor C may be reached in a short time—in the present example within about 12 ms. Subsequent to pre-charge completion (e.g., Vcap within several percent of Vs), the gate driver 328 controls the switch to the full on saturation state (essentially 100% duty cycle) and the resettable fuse device 110 operates in the circuit protection mode. FIG. 4B illustrates an exemplary block diagram of a portion of the resettable fuse device 110 relevant to the PWM mode pre-charge mode and circuit protection mode of operation. The source voltage Vs is shown supplying current to the power converter module 28 through current sensor 120 and switch module 112. A transient voltage suppression device 401 may be across the switch module 112 and current sensor 120 to absorb turn off transients. The gate drive 328 may provide a gate drive signal to the switch module 112 to control it on (closed in saturation) or off (open) in either of the pre-charge mode or the circuit protection mode.

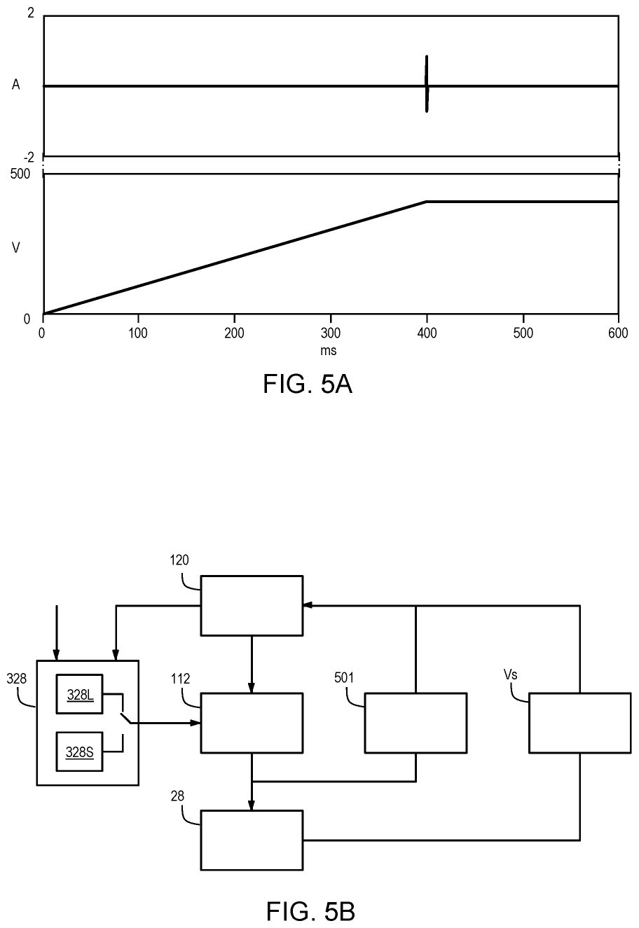

In an embodiment, the electronically resettable fuse device 110 may be operated in a pre-charge mode wherein the gate driver 328 operates the switch module 112 in a linear mode wherein the switch module 112 is operated like a controllable resistance in a linear operating region for controllably pre-charging of the DC link capacitor C. The switch module 112 in the present embodiment may be a single switch device which may be controlled in a linear region of operation. In an embodiment, the gate driver 328 may include a linear op-amp circuit to provide a linear mode gate control signal by comparing a milliamp level reference current to a milliamp level current sensor signal from a low-range current sensor in series with the current sensor 120 or from a dual-range current sensor 120 with appropriate gain thereby controlling the switch module 112 in its linear region to a setpoint corresponding to the milliamp level reference. As used herein, dual-range current sensor 120 may refer to a single current sensor accurate in both switch module 112 linear modes (e.g., milliamps) and full on saturation modes (tens of amps) or individual current sensors accurate in respective linear modes (e.g., milliamps) or full on saturation modes (tens of amps) with selective output utilization. Since operation in the switch module 112 linear region results in a large voltage drop across the switch module 112 (e.g., almost full source voltage), current limiting to the milliamp range is required to manage power dissipation through the switch module 112. FIGS. 5A and 5B illustrate an exemplary linear mode of pre-charging operation with time shown horizontally in milliseconds (ms). The top chart of FIG. 5A plots the current in amps (A) with respect to time into a 10 uF DC link capacitor C from nominally zero volts being pre-charged from a 400 volt DC source at about one milliamp. The bottom chart of FIG. 5A plots the voltage (V) with respect to time across the 10 uF DC link capacitor C being pre-charged in accordance with the top chart. It is appreciated that the power dissipation through the switch module 112 is manageable at about 4 watts (400 volts×1 milliamp). The small current at 1 milliamp requires more time to fully charge the DC link capacitor C at about 400 ms but, advantageously, does not subject the switch module 112 to high current transient stresses or high-power dissipation. In one embodiment, the timing of the transition may be chosen to coincide with transient current through the switch module 112 that is at or below the maximum current rating of the switch. Subsequent to pre-charge completion (e.g., Vcap within several percent of Vs), the gate driver 328 controls the switch to the full on saturation state and the resettable fuse device 110 operates in the circuit protection mode. At this transition, transient current may remain very low at below 1 amp at 400 ms in the present example. FIG. 5B illustrates an exemplary block diagram of a portion of the resettable fuse device 110 relevant to the linear mode pre-charge mode and circuit protection mode of operation. The source voltage Vs is shown supplying current to the power converter module 28 through current sensor 120 and switch module 112. The current sensor provides a current signal Cs to the gate drive 328 and a reference current Vp is also provided to the gate drive 328. A transient voltage suppression device 501 may be across the switch module 112 and current sensor 120 to absorb turn off transients. The gate drive 328 may selectively provide a first gate drive signal 328L (e.g., linear gate control signal) to the switch module 112 to control it in a linear region during the linear mode pre-charge mode or a second gate drive signal 328S to the switch module 112 to control it on (closed in saturation) or off (open) in the circuit protection mode. The first gate drive signal 328L for linear control may be provided from a linear op-amp circuit providing the linear mode gate control signal by comparing reference current Vp to current sensor signal Cs.

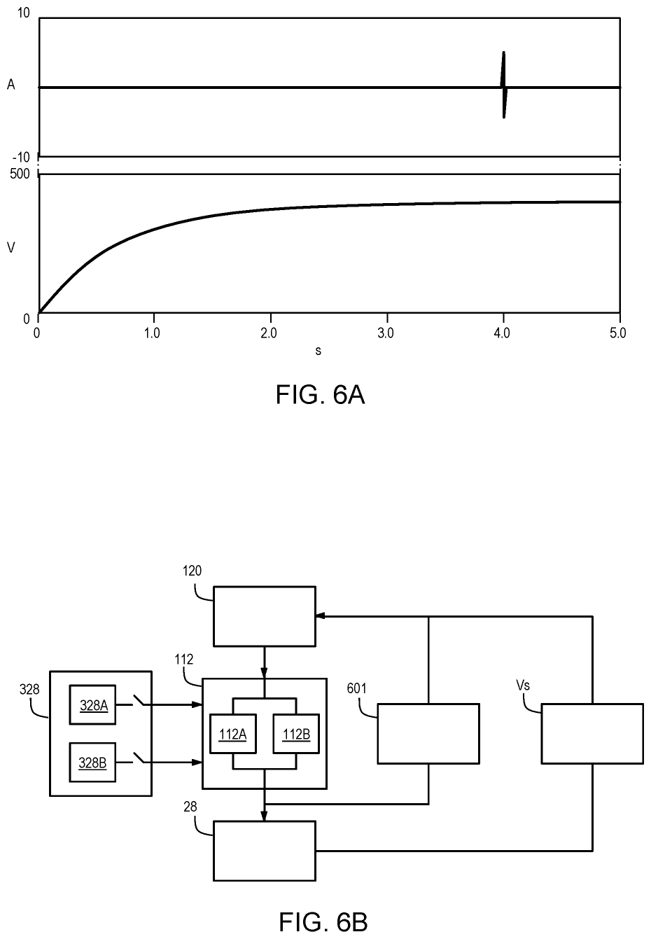

In an embodiment, the electronically resettable fuse device 110 may include an addition low current switch and current limiting resistor for use in a pre-charge mode. In an embodiment, the switch module 112 may include a parallel combination of independently selectable controlled switch devices. Thus, in an embodiment, the electronically resettable fuse device 110 may operate in a pre-charge mode selectively supplying current through a first switch device and resistor to pre-charge the DC link capacitor. The electronically resettable fuse device 110 may operate in a circuit protection mode selectively supplying current through a second switch to provide current to the load. One switch device may be series combined with a current limiting resistor to provide a pre-charge current path while the current path associated with the other switch device has no current limiting resistor. The gate driver 328 may operate the first switch device and resistor combination in an on state and the second switch device in the off state while operating in a pre-charge mode for controllably pre-charging of the DC link capacitor C. The gate driver 328 may operate the second switch device in an on state and the first switch device and resistor combination in an off state while operating in a circuit protection mode. FIGS. 6A and 6B illustrate an exemplary pre-charging mode of operation with time shown horizontally in seconds(s). The top chart of FIG. 6A plots the current in amps (A) with respect to time into a 10 uF DC link capacitor C from nominally zero volts being pre-charged from a 400 volt DC source through a 50 kOhm resistor at an initial current of about 8 milliamps (400 volts/50 kOhm). Alternative current limiting resistor values may be chosen in accordance with the desired charge time of the DC link capacitor C and current limitations of the first switch device. The bottom chart of FIG. 6A plots the voltage (V) with respect to time across the 10 uF DC link capacitor C being pre-charged in accordance with the top chart. Advantageously, the current limiting resistor does not subject the first switch device to high current transient stresses or high-power dissipation. Subsequent to pre-charge completion (e.g., Vcap within several percent of Vs), the gate driver 328 controls the first switch device off and the second switch device to the full on saturation state and the resettable fuse device 110 operates in the circuit protection mode. At this transition, transient current may remain very low at below 5 amps at 4 s in the present example. In one embodiment, the timing of the transition may be chosen to coincide with transient current through the switch module 112 that is at or below the maximum current rating of the switch. FIG. 6B illustrates an exemplary block diagram of a portion of the resettable fuse device 110 relevant to the pre-charge mode and circuit protection mode of operation using first and second switch devices and a current limiting resistor. The source voltage Vs is shown supplying current to the power converter module 28 through current sensor 120 and switch module 112. A transient voltage suppression device 601 may be across the switch module 112 and current sensor 120 to absorb turn off transients. The switch module 112 may include a first switch device 112A and current limiting resistor combination and a second switch device 112B. The gate drive 328 may selectively provide a first gate drive signal 328A to the first switch device 112A and current limiting resistor combination to control the first switch device 112A on during the pre-charge mode or a second gate drive signal 328B to the switch device 112B to control it on (closed in saturation) or off (open) in the circuit protection mode. In the present embodiment, pre-charge mode, circuit protection mode and transitions may advantageously be performed using simple discrete logic and logic control signals and a calibrated time delay sufficient to allow pre-charging of the DC link capacitor through the first switch device 112A before switching on the second switch device 112B. Internal current or voltage sensing within the resettable fuse device 110 may alternatively provide comparative information for controlling transition timing.

In some embodiments, pre-charge mode termination may be triggered by current threshold comparisons to the current sensor 120 output. In other embodiments, the voltage measured across the switch module 112 and the source voltage Vs may provide comparative information from which the termination may be triggered. In other embodiments, external voltage measurements across the DC link capacitor and source voltage Vs may provide comparative information from which the termination may be triggered.

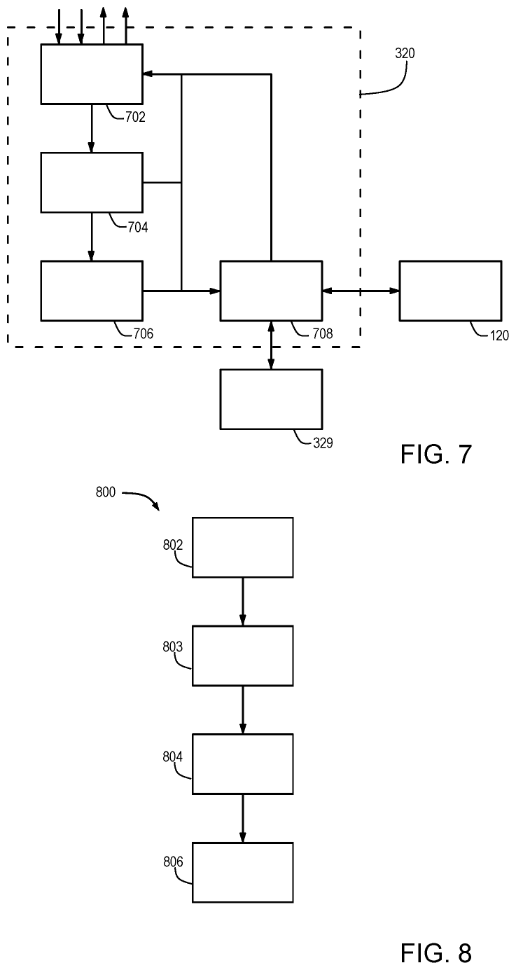

FIG. 7 depicts schematic diagram of the microcontroller 320 of FIGS. 3A and 3B according to one or more embodiments described herein. Although labeled as a microcontroller, the microcontroller 320 may be any suitable type of processing device for executing programmatic instructions. The microcontroller 320 may include, for example, a processor for executing programmatic instructions stored in a memory. Examples of the microcontroller 320 may include a system on a chip, a programmable logic controller (PLC), a digital signal processor (DSP), and the like. According to one or more embodiments described herein, the microcontroller 320 may include, for example, a processor for executing programmatic instructions stored in a memory.

The microcontroller 320 maintains system integrity and functionality. The microcontroller 320 also generates gate responses for the gate driver 328 based on feedback from the sensor 120 and other information (e.g., historical data).

At block 702, the microcontroller 320 interfaces with a master controller (not shown), such as via the control signals 324 of FIGS. 3A and 3B. This may include sending and/or receiving data/information between the microcontroller 320 and the master controller. For example, if the microcontroller 320 detects a high current event, the microcontroller 320 may alert the master controller. As another example, the master controller may communicate threshold settings to the microcontroller 320 to adjust one or more thresholds, such as the time-based current threshold, the instantaneous current threshold, etc., as described herein.

At block 704, the microcontroller 320 is initialized. This may include a boot process for the microcontroller 320.

At block 706, the microcontroller 320 performs communication checks. For example, the microcontroller 320 may establish and/or test communication between itself and various devices, such as a low-voltage power supply (e.g., the isolated power supply 332), a high-voltage power supply (e.g., the battery pack 24), a gate driver (e.g., the gate driver 328), sensors (e.g., the sensor 120), and the like.

At block 708, the microcontroller 320 performs tasks that may include reading commands, reading sensor feedbacks/data, generating gate control outputs, and the like. The features and functionality of the microprocessor, including the block 708, are described with further reference to FIG. 8.

In particular, FIG. 8 depicts a flow diagram of a method 800 for monitoring an electric circuit according to one or more embodiments described herein. The method 800 may be performed by any suitable system or device such as the microcontroller 320 of FIGS. 3A, 3B, and 7, or any other suitable processing system and/or processing device (e.g., a processor). The method 800 is now described with reference to the elements of FIGS. 2-7 but is not so limited.

At block 802, the microcontroller 320 monitors an electric circuit (e.g., the electrical system 100) of a vehicle (e.g., the vehicle 12). As described herein, the electric circuit may include a battery source (e.g., the battery pack 24) and a load (e.g., power inverter modules 26, power converter modules 28, and associated electrical loads) such that the battery source supplies electric power to the load. Particularly, the microcontroller 320 monitors the electric circuit to effect pre-charging and circuit protection functions.

For example, at block 803, the microcontroller 320 may invoke a pre-charge of a power converter module 28 at any point during vehicle operation or quiescent periods of non-operation requiring electrical power from the converter module 28. For example, vehicle preconditioning in anticipation of operator use may require electrical power from an idle converter module 28 for in cabin heating or cooling. Thus, for example, a master controller (not shown) may request pre-charging of the converter module 28 in order to bring the converter module 28 online for power delivery to required auxiliary loads. Block 803 may effect the monitoring of currents and voltages from sensors (e.g., sensors 120) of the resettable fuse device 110 or external sensors as described herein in order to monitor the progress of pre-charging and to transition the resettable fuse device 110 from a pre-charging mode to a circuit protection mode as described herein.

At block 804, the microcontroller 320 operating the resettable fuse device 110 in a circuit protection mode may detect a high current event in the electric circuit by comparing a current level of a current flowing through the electric circuit to a time-based current threshold. The microcontroller 320 may receive the current level from a sensor (e.g., the sensor 120).

As described herein, the time-based current threshold may include a time limit and a current level limit. The microcontroller 320 detects a high current event responsive to determining that the current level of the current flowing through the electric circuit meets or exceeds the current level limit for a duration exceeding the time limit. In some examples, multiple time-based current thresholds may be implemented, for example, a first time-based current threshold and a second time-based current threshold. The multiple time-based current thresholds may be different combinations of current level limits and time limits. For example, a first time-based current threshold could set a current level limit of 200 amps for a time limit of 0.5 seconds while a second time-based current threshold could set a current level limit of 300 amps for a time limit of 0.1 seconds. In the case of multiple time-based current thresholds, the microcontroller 320 may detect a high current event responsive to determining that the current level of the current flowing through the electric circuit exceeds the first current level limit for a first duration exceeding the first time limit or determining that the current level of the current flowing through the electric circuit exceeds the second current level limit for a second duration exceeding the second time limit.

According to one or more embodiments described herein, the time-based current threshold may be adjusted. Adjusting the threshold provides for considering lifetime-based factors of the load. For example, a certain load may be more susceptible to failure due to a high current event as that load ages. In such cases, the time-based current threshold may be adjusted (e.g., the time limit may be shortened and/or the current level limit may be lowered). In some examples, the time-based current threshold may be adjusted based at least in part on an operating condition of the vehicle (e.g., ambient temperature, elevation/altitude, etc.). In yet another example, the time-based current threshold may be adjusted based on data collected from other vehicles. For example, if it becomes apparent (based on data from other vehicles) that a particular type of electric load is susceptible to failure at a time-based current threshold other than what is originally set, the time-based current threshold may be adjusted.

The microcontroller 320 may also detect an instantaneous high current event. For example, the microcontroller 320 detects an instantaneous high current event in the electric circuit by comparing the current level of the current flowing through the electric circuit to an instantaneous current threshold. The instantaneous current threshold may include a current level limit but no time-based component or limit. Thus, if the current level exceeds the instantaneous current threshold for any amount of time, an instantaneous high current event is said to have occurred.

Responsive to a high current event being detected at block 804, the microcontroller 320, at block 806, controls, a gate driver (e.g., the gate driver 328) to cause a switch (e.g., the switch module 112) of an electronically resettable fuse (e.g., the electronically resettable fuse device 110) to open the electric circuit to stop the flow of the current to the electric motor. Particularly, the microcontroller 320 may cause the gate driver 328 of the electronically resettable fuse device 110 to open the switch module 112 to stop the flow of the current to the electric motor.

Additional processes also may be included, and it should be understood that the process depicted in FIG. 8 represents an illustration and that other processes may be added or existing processes may be removed, modified, or rearranged without departing from the scope and spirit of the present disclosure.

The terminology used herein is for the purpose of describing particular embodiments only and is not intended to be limiting. The terms “a” and “an” do not denote a limitation of quantity, but rather denote the presence of at least one of the referenced items. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

All numeric values herein are assumed to be modified by the term “about” whether or not explicitly indicated. For the purposes of the present disclosure, ranges may be expressed as from “about” one particular value to “about” another particular value. The term “about” generally refers to a range of numeric values that one of skill in the art would consider equivalent to the recited numeric value, having the same function or result, or reasonably within manufacturing tolerances of the recited numeric value generally. Similarly, numeric values set forth herein are by way of non-limiting example and may be nominal values, it being understood that actual values may vary from nominal values in accordance with environment, design and manufacturing tolerance, age and other factors.

When an element such as a layer, film, region, or substrate is referred to as being “on” another element, it may be directly on the other element or intervening elements may also be present. In contrast, when an element is referred to as being “directly on” another element, there are no intervening elements present. Therefore, unless explicitly described as being “direct,” when a relationship between first and second elements is described in the above disclosure, that relationship may be a direct relationship where no other intervening elements are present between the first and second elements but may also be an indirect relationship where one or more intervening elements are present (either spatially or functionally) between the first and second elements.

One or more steps within a method may be executed in different order (or concurrently) without altering the principles of the present disclosure. Further, although each of the embodiments is described above as having certain features, any one or more of those features described with respect to any embodiment of the disclosure may be implemented in and/or combined with features of any of the other embodiments, even if that combination is not explicitly described. In other words, the described embodiments are not mutually exclusive, and permutations of one or more embodiments with one another remain within the scope of this disclosure.

Unless defined otherwise, technical and scientific terms used herein have the same meaning as is commonly understood by one of skill in the art to which this disclosure belongs.

Unless specified to the contrary herein, all test standards are the most recent standard in effect as of the filing date of this application, or, if priority is claimed, the filing date of the earliest priority application in which the test standard appears.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method comprising:
controlling a gate driver to cause a switch module of an electronically resettable fuse to control an electric current to pre-charge a DC link capacitor of a power converter;
monitoring, using a microcontroller, an electric circuit of a vehicle, the electric circuit comprising a battery source and a load including the power converter, wherein the battery source supplies electric power to the load;
detecting, using the microcontroller, a high current event in the electric circuit by comparing a current level of a current flowing through the electric circuit to a time-based current threshold; and
responsive to detecting the high current event, controlling the gate driver to cause the switch module of the electronically resettable fuse to open the electric circuit to stop the flow of the current through the electric circuit.

2. The method of claim 1, further comprising updating the time-based current threshold based at least in part on data collected from other vehicles

3. The method of claim 1, wherein the switch module comprises a switch device and controlling the electric current includes pulse width modulating the switch device.

4. The method of claim 1, wherein the switch module comprises a switch device and controlling the electric current includes controlling the switch device in a linear operating region.

5. The method of claim 1, wherein the switch module comprises a first switch device and a second switch device wherein the first switch device is in series with a current limiting resistor and controlling the electric current includes controlling the first switch device on.

6. A vehicle comprising:
an on-vehicle battery source to provide electric current to an electric circuit including a power converter with a direct current (DC) link capacitor;
an electronically resettable fuse for passing the electric current between the battery source and the electric circuit; and
a microcontroller to selectively control the electronically resettable fuse in one of a pre-charge mode and a circuit protection mode, wherein the pre-charge mode limits a rate of charging of the DC link capacitor with the electric current.

7. The vehicle of claim 6, wherein the power converter comprises one of a power inverter providing a multi-phase alternating current (AC) output to an electric machine and a DC/DC power converter providing a DC output to an auxiliary load.

8. The vehicle of claim 7, wherein the DC output to the auxiliary load comprises a DC output at a voltage level that is less than or equal to the voltage level of the battery source.

9. The vehicle of claim 7, wherein the DC output to the auxiliary load comprises a DC output at a voltage level that is greater than or equal to the voltage level of the battery source.

10. The vehicle of claim 6, wherein the power converter comprises a power inverter and an associated electric machine windings selectively reconfigured and controlled to function as a buck or boost mode converter.

11. The vehicle of claim 6, wherein the power converter is coupled to off-vehicle loads through a charge port.

12. The vehicle of claim 7, wherein the power converter comprises the DC/DC power converter and the pre-charge mode and the circuit protection mode remain active during a key-off non-propulsion mode of the vehicle.

13. An electric circuit, comprising:
a battery source to provide electric current to a power converter having a direct current (DC) link capacitor;
an electronically resettable fuse for passing the electric current between the battery source and the power converter through a switch module; and
a microcontroller to selectively control the electronically resettable fuse in one of a pre-charge mode and a circuit protection mode, wherein the pre-charge mode limits a rate of charging of the DC link capacitor by controlling the electric current with the switch module.

14. The electric circuit of claim 13, wherein the switch module comprises a switch device and controlling the electric current with the switch module includes pulse width modulation of the switch device.

15. The electric circuit of claim 14, wherein the pulse width modulation of the switch device comprises a fixed duty cycle.

16. The electric circuit of claim 14, wherein the pulse width modulation of the switch device comprises a variable duty cycle.

17. The electric circuit of claim 13, wherein the switch module comprises a switch device and controlling the electric current with the switch module includes controlling the switch device in a linear operating region.

18. The electric circuit of claim 13, wherein the switch module comprises a first switch device and a second switch device wherein the first switch device is in series with a current limiting resistor and controlling the electric current with the switch module includes controlling the first switch device on.

19. The electric circuit of claim 13, further comprising a transient voltage suppression device across the switch module.

20. The electric circuit of claim 13, wherein the switch module comprises a bi-directional switch device.
